(19) United States
(12) Patent Application Publication
(10) Pub. No.: US 2005/0056829 A1
(43) Pub. Date: Mar. 17, 2005

(54) Reducing dark current of photoconductor using heterojunction that maintains high x-ray sensitivity

(76) Inventors: Michael C. Green, Palo Alto, CA (US); Steve Bandy, Sunnyvale, CA (US); George Zentai, Mountain View, CA (US); Larry Dean Partain, Los Altos, CA (US)

Correspondence Address: Daniel E. Ovanezian;BLAKELY, SOKOLOFF, TAYLOR & ZAFMAN LLP, Seventh Floor, 12400 Wilshire Boulevard, Los Angeles, CA, 90025-1026, US

(21) Appl. No.: 10/665,298

(22) Filed: Sep. 17, 2003

(51) Int. Cl. H01L 29/08

(52) U.S. Cl. 257/40

(57) ABSTRACT

A photodetector having a heterojunction structure is described that may operate to reduce contact corrosion and/or reduce dark current while maintaining high x-ray sensitivity. The heterojunction structure may be formed by a plurality of halide semiconductor materials.

### TECHNICAL FIELD

Embodiments of the present invention are generally related to the field of photodetectors and more specifically related to semiconductor based radiation detectors.

### BACKGROUND

Detectors may be fabricated in many ways, and may serve many purposes. For all detectors, sensitivity and signal-to-noise ratios are important to successful operation. When attempting to detect x-rays, photodetectors are preferably highly sensitive to x-rays and relatively insensitive to other electromagnetic radiation. Photodetectors are constructed with photoconductor sensors. The photoconductors can either be intrinsic semiconductor materials that have high resistivity unless illuminated by photons, or diode structures that have small currents due to the blocking effect of the diode junction unless illuminated.

FIG. 1A illustrates one type of conventional photodetector 50 that includes a semiconductor material with a pair of contact electrodes on either side of the semiconductor material. The semiconductor material, upon which radiation is incident through the top contact electrode, acts as a direct conversion layer to convert incident radiation to electric currents. A voltage source connected to the electrodes applies a positive bias voltage across the semiconductor material, and current is observed as an indication of the magnitude of incident radiation. When no radiation is present, the resistance of the semiconductor material is high for most photoconductors, and only a small dark current can be measured. When radiation is made incident through the top contact electrode upon the semiconductor material, electron-hole pairs form and drift apart under the influence of a voltage across that region. Electrons are drawn toward the more positively (+) biased contact electrode and holes are drawn toward the more negatively biased (e.g., quasi-grounded) contact electrode. Formation of electron-hole pairs occurs due to interaction between the incident radiation and the semiconductor material. If the x-rays have energy greater than the band gap energy of the semiconductor material, then electron-hole pairs are generated in the semiconductor as each photon is absorbed in the material. If a voltage is being continuously applied across the semiconductor material, the electron and hole will tend to separate, thereby creating a current flowing through the photodetector. The magnitude of the current produced in the photodetector is related to the magnitude of the incident radiation received. After removal of the incident radiation, the charge carriers (electrons and holes) remain for a finite period of time until they either reach the collection electrodes or can be recombined. The term “charge carriers” is often used to refer to either the electrons, or holes, or both.

Among semiconductor materials considered for x-ray detectors are selenium, mercuric iodide and lead iodide. The two iodide compounds have a higher mobility product, require a much lower polarizing voltage than selenium, and have additional advantages such as greater temperature stability. However, each of mercuric iodide and lead iodide has physical parameters that affect their performance and ease of use in single layer x-ray detectors.

In mercuric iodide, the carrier mobility is measured to be higher than lead iodide and the lag time is found to be lower. The lower carrier mobility means that it is difficult to use a thick layer of lead iodide, which is more efficient in absorbing a greater fraction of incident x-ray photons, especially at higher photon energies that increase detector sensitivity. However, mercuric iodide is more chemically reactive toward typical contact materials (e.g., aluminum) than is lead iodide and considerable problems have been experienced with contact corrosion in flat panel detectors coated with mercuric iodide.

As mentioned above, photoconductors may also have diode structures based on either a p-i-n or p-n configuration. FIG. 1B illustrates a conventional p-i-n diode. Such a photodiode 100 is termed a “p-i-n” diode for the configuration of semiconductor material in the diode. Photodiode 100 is composed of a p-doped semiconductor (p-type) material layer 110 and an n-doped semiconductor (n-type) material layer 130. Light is made incident on the depletion region between the p-type and the n-type material layers, creating electron-hole pairs and thus a current. To control the thickness of the depletion region, a layer 120 of intrinsic (i) material is inserted between the p-doped semiconductor material layer 110 and the n-doped semiconductor material layer 130. This structure may be used to detect an x-ray which is incident on either the p-doped semiconductor 110 or the n-doped semiconductor 130. Photodetectors based on a p-i-n structure also include contacts to apply bias to the material layers, as illustrated in FIG. 1C. Photodetector 150 includes a top contact conductor 181 connected to p-doped region 182 and a bottom contact conductor 285 connected to n-doped region 284. P-doped region 282, intrinsic layer 283 and n-doped region 284 are all semiconductor materials as described with respect to detector 100. The layers are formed on a substrate 286 that acts as a base for the detector 150.

As mentioned above, the p-i-n structure may be used to detect x-rays that are incident on either of the p-doped semiconductor material layer 282 or the n-doped semiconductor material layer 285. In operation of p-i-n photodiode 150, a reverse-bias voltage is applied across the photodiode and x-rays are made incident upon the intrinsic region 283. The electron-hole pairs then separate under the applied electric field and quickly migrate toward their respective poles. The electrons move toward the positive pole and the holes move toward the negative pole. Conventional photodiodes have narrow intrinsic regions 283. Due to the narrowness of the intrinsic region 283 and also due to the high mobility of the intrinsic material, there is little chance that the carriers will recombine before they arrive at the interface with the doped material. The electrons and holes then collect near the respective interface with the doped material. The change in resistivity results in a change in one or both of a voltage or current between top conductor 281 and second conductor 286, which may be measured in a surrounding system (not shown).

One problem with prior diode structure photoconductors is that dark (leakage) current limits the usefulness of the high x-ray sensitivity of photoconductor sensors. One solution to substantially reducing such dark current is by using p-n heterostructures of photoconductors. Diodes structures (p-n and p-i-n) may be composed of two or more dissimilar semiconductor materials, thereby forming a heterojunction. For example, one prior photodetector consists of a layer of cadmium telluride and a layer of cadmium sulfide forming a heterojunction. The cadmium telluride is deposited so that it is a p-type material (excess holes) and the cadmium sulfide is deposited so that it is an n-type material (excess electrons). An external voltage applied across the heterojunction of the two materials produces a p-n junction that acts as a photodiode. As discussed above, radiation induced electron-hole pairs give rise to electrical currents that flow in proportion to the incident radiation. The p-n junction, when reversed biased, inhibits dark current from flowing across the junction.

The performance of a photoconductor may be judged by various criteria including sensitivity. Sensitivity refers to the current produced by a photoconductor with respect to the electromagnetic power. A photoconductor with high sensitivity will produce more current for a given intensity of incident radiation than one with a low sensitivity. Sensitivity is affected by the mobility of the electrons in the material. Semiconductor materials with a higher mobility have a higher sensitivity, if other parameters are similar, because the electrons can move at a greater speed. One problem with prior heterojunction photoconductors is that they exhibit low sensitivity.

### SUMMARY

A photodetector is described. In one embodiment, the photodetector comprises a first semiconductor material, a second semiconductor material coupled to the first semiconductor material, and a contact coupled to the second semiconductor material. The second semiconductor material being less corrosive than the first semiconductor material to the contact.

In another embodiment, the photodetector comprises a plurality of semiconductor materials forming a heterojunction. The plurality of semiconductor materials comprises a first semiconductor material and a second semiconductor material coupled to the first semiconductor material. The first and second semiconductor materials may be halides.

In one particular embodiment, the first semiconductor material comprises lead iodide and the second semiconductor material comprises mercuric iodide.

Other features and advantages of the present invention will be apparent from the accompanying drawings, and from the detailed description, which follows below.

### BRIEF DESCRIPTION OF THE DRAWINGS

The present invention is illustrated by way of example and not limitation in the accompanying figures in which:

FIG. 1A illustrates one conventional photoconductor.

FIG. 1B further illustrates the conventional photoconductor of FIG. 1A.

FIG. 1C illustrates another conventional photoconductor.

FIG. 2A illustrates one embodiment of a heterojunction photodetector.

FIG. 2B illustrates an alternative embodiment of a heterojunction photodetector.

FIG. 3 illustrates one embodiment of a method of fabricating a heterojunction photodetector.

FIG. 4 illustrates one embodiment of a method of operating photodetector 200.

FIG. 5 illustrates one embodiment of an x-ray detection system.

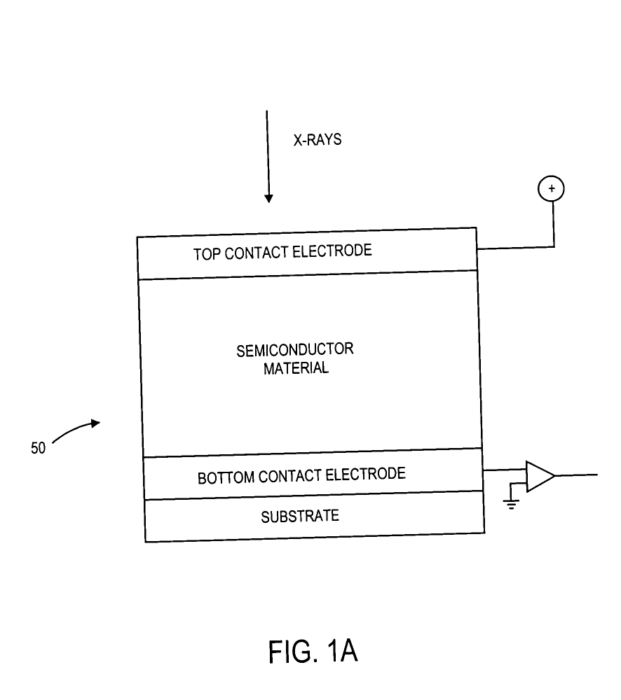

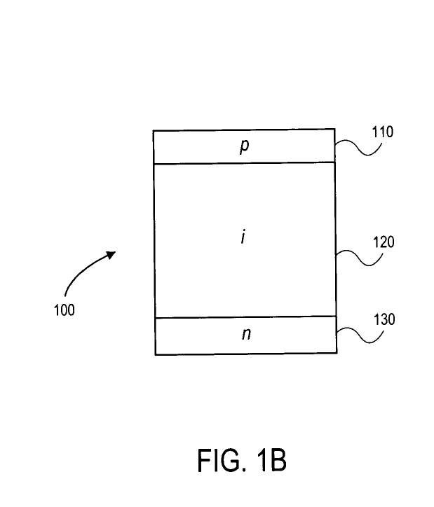

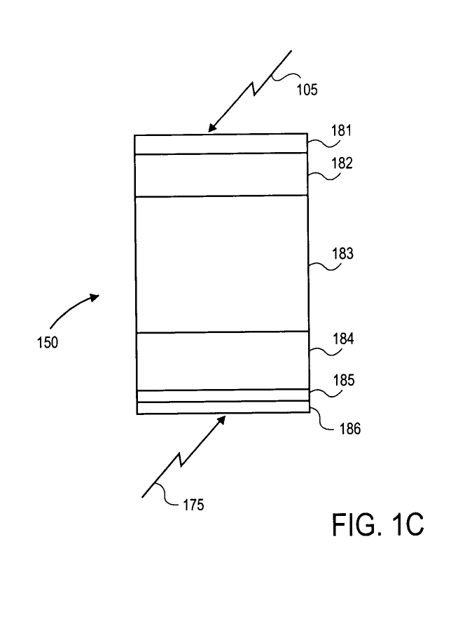

### DETAILED DESCRIPTION

In the following description, numerous specific details are set forth such as examples of specific components, processes, etc. in order to provide a thorough understanding of the present invention. It will be apparent, however, to one skilled in the art that these specific details need not be employed to practice the present invention. In other instances, well known components or methods have not been described in detail in order to avoid unnecessarily obscuring the present invention.

The terms “top,” “bottom,” “front,” “back,” “above,” “below,” and “between” as used herein refer to a relative position of one layer or component with respect to another. As such, one layer deposited or disposed above or below another layer, or between layers, may be directly in contact with the other layer(s) or may have one or more intervening layers. The term “coupled” as used herein means connected directly to or connected indirectly through one or more intervening layers or operatively coupled through non-physical connection (e.g., optically).

A photodetector having a heterojunction structure is described that may operate to reduce contact corrosion and/or reduce dark current while maintaining high x-ray sensitivity. Instead of using a single, thick semiconductor photoconductor layer (e.g., of mercuric iodide), a multiple layer heterojunction structure is employed.

In one particular embodiment, for example, the photodetector includes a layer of lead iodide (PbI₂) and a thicker layer of mercuric iodide (HgI₂) disposed above to form a bi-layer PbI₂—HgI₂ coating film. A thin top layer of lead iodide may also be disposed above the mercuric iodide layer to form a three-layer PbI₂—HgI₂—PbI₂ “sandwich” structure. Alternatively, other semiconductor materials may be used for any of the layers as discussed below.

An advantage of such a structure is that the outer contacts on the coating film may be protected from chemical attack by the mercuric iodide layer because of the presence of the intervening layer(s) of relatively unreactive lead iodide, while maintaining a high mobility in the photoconductor due to the thicker higher mobility layer. The mobility of electrons in mercuric iodide is higher than the mobility of holes. In lead iodide, the mobility of holes is higher than electrons. In general, the mobility of electrons in mercuric iodide is higher the mobility of holes in lead iodide, thus making mercuric iodide a better photoconductor material because it can more effectively collect charges with a lower bias. As such, by using a thicker layer of mercuric iodide, the overall carrier transport properties of the photoconductor may be dominated by the mercuric iodide layer that constitutes the bulk of the photodetector's thickness.

Further, such a structure may operate to reduce dark current in the photoconductor. Although the band gaps of mercuric iodide and lead iodide are approximately the same (e.g., differing by less than 10%), the slight difference in the band gap and carrier mobilities in mercuric iodide and lead iodide may lead to quasi p-n junction behavior at the layer interfaces that may operate to reduce dark current, in particular, when operated under reverse bias conditions.

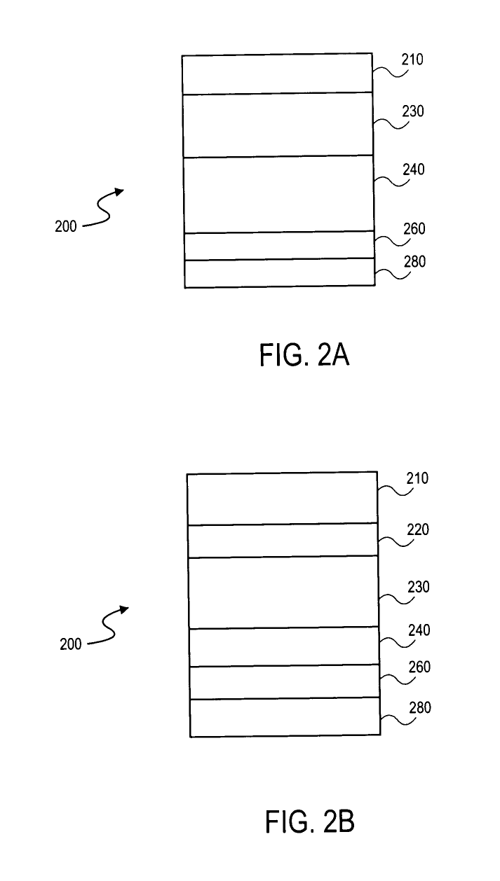

FIG. 2A illustrates one embodiment of a photodetector. In this embodiment, photodetector 200 includes a substrate 280, a first contact 260, a first semiconductor material 240 coupled to the contact 260, a second semiconductor material 230 coupled to first semiconductor material 240, and a second contact 210 coupled to second semiconductor material 230. Contacts 210 and 260 are constructed from conducting materials, for examples, palladium and indium tin oxide (ITO). Alternatively, other conducting materials such as aluminum may be used.

In one particular embodiment, first semiconductor material 240 may be composed of PbI₂ and second semiconductor material 230 may be composed of HgI₂. As noted above, an HgI₂ layer 230 is preferably thicker than a PbI2 layer 240. HgI₂ may have superior properties for x-ray detection, making its inclusion in one embodiment of photodetector 200 advantageous. However, use of HgI₂ as a semiconductor material, by itself, in a photodetector may be problematic, as it may be chemically reactive with one or both conductors 260 and 210. As such, a thin layer of PbI₂ may be used as semiconductor material 240 as a buffer between the HgI₂ semiconductor material layer 230 and either of contacts 260 and 210 (or both as discussed below in relation to FIG. 2B) to reduce reactive effects, while allowing the thicker HgI₂ layer to dominate the performance characteristics of the heterojunction structure.

Various thickness relationships between the two semiconductor materials 230 and 240 may be used. For example, first semiconductor material layer 240 may be thin and the semiconductor material layer thick relative to each other. In one embodiment, first semiconductor material 240 may have a thickness less than 250 microns (μm), for examples, 10, 40 or 150 microns. The second semiconductor material 230 may have a thickness greater than 250 microns, for examples, 200, 350 or 450 microns. Note that the specific thickness need not be matched up respectively, such that a 10 microns first semiconductor material thickness and 450 microns second semiconductor thickness may be used together. In another embodiment, two relatively medium thickness layers (such as two 150 micron layers for example) may be used. In an alternative embodiment, the first semiconductor material 240 may be thicker than second semiconductor material 230, for example, to further remove second semiconductor material 230 from contact 260. It should be noted that the semiconductor materials may have thickness outside the exemplary ranges provided above and, in particular, the primary detection material (e.g., semiconductor material 230) depending on the particular application (e.g., mammography, general radiography, industrial, etc.) in which photodetector 200 will be used. For example, first semiconductor material 240 may have a thickness on the order of Angstroms and the second semiconductor material 230 may have a thickness on the order of millimeters.

In addition, reactive problems with contact 210 may also be reduced with a sandwich approach by the use of an additional semiconductor material as illustrated in FIG. 2B. FIG. 2B illustrates another alternate embodiment of photodetector 200 having three semiconductor layers. Another semiconductor layer 220 may be disposed between second semiconductor material 230 and contact 210. In one embodiment, the chemical reactive properties of semiconductor material 220 may be similar to that of semiconductor material 240 to provide a less corrosive interface to contact 210.

In one embodiment, both layers 220 and layer 240 (e.g., the PbI₂ layers) are thinner than layer 230 (e.g., the HgI₂ layer). The resulting structure may be expected to have the properties of HgI₂ for detection purposes, without the corresponding reactive properties of a single layer, HgI₂, photodetector.

In alternative embodiments, semiconductor materials other than mercuric iodide and lead iodide may be used, such as other semiconductor halides, for example. In one embodiment, such alternative materials may be iodide compounds such as bismuth iodide (BiI₂). Alternatively, non-iodide compounds and may be used, for example, thallium bromide (TlBr). The semiconductor materials selected for use may operate as a corrosion barrier layer to a contact and/or as part of the heterojunction structure to optimize the electric parameters of the detector (e.g., reduce dark currents). The other semiconductor materials that may be used for semiconductor materials 240 and/or 230 may have band gaps approximately the same or different than either of mercuric iodide (2.1 eV) and lead iodide (2.3 eV). For example, bismuth iodide has a band gap of 1.73 eV and thallium bromide has a band gap of 2.7 eV. As previously noted, yet other halides may also be used for the semiconductor material layers.

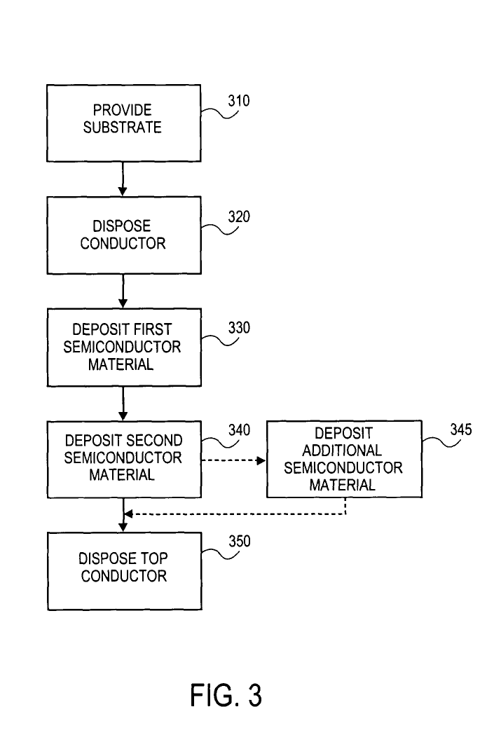

FIG. 3 illustrates one embodiment of a method of making a photodetector. The method involves fabrication of photodetectors, such as those previously illustrated, with a heterojunction structure. In step 310, substrate 280 (e.g., composed of glass) is provided. In step 320, conductor 260 (e.g., Pd) is disposed on the substrate 280 using any one of various techniques that are known in the art, for examples, coating, plating, chemical vapor deposition (CVD), sputtering, ion beam deposition, etc. In step 330, a first semiconductor material 240 (e.g., PbI₂) is deposited above the conductor 260. In step 340, a second semiconductor material 230 (e.g., HgI₂) is deposited above the semiconductor material 240. The semiconductor materials 240 and 230 may be deposited using any one of various techniques known in the art, for examples, chemical vapor deposition (CVD), sputter, ion beam deposition, etc. In step 350, a conductor 210 is disposed on the semiconductor material 230.

In an alternative embodiment, as discussed above, the photoconductor may include additional semiconductor materials. In one such embodiment, an additional semiconductor material is deposited above the semiconductor material 230, step 345, thereby sandwiching the semiconductor material 230.

It should be noted that the process illustrated is simplified, and may involve patterning (such as for isolation of individual conductors for example). Furthermore, a self-aligned process may be used, in which individual detectors are separated out through etching of some form after formation of layers on the substrate.

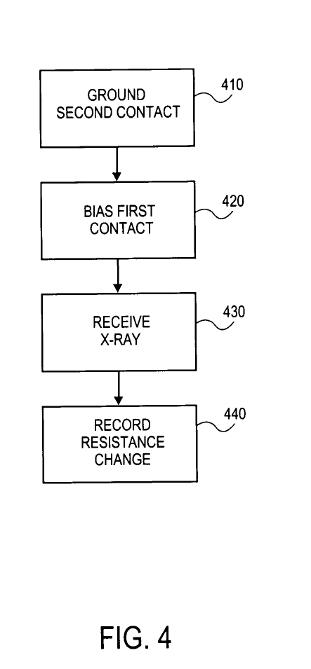

FIG. 4 illustrates one embodiment of a method of operating photodetector 200. At block 410, contact 260 is coupled to ground. At block 420, contact 210 is biased to a negative voltage. At block 430, photodetector 200 is oriented such that x-rays are received through contact 210. Alternatively, other biases and x-ray receipt configuration may be used. At block 440, a surrounding system 500 records the change in resistance (as a current or voltage change) and thereby registers the presence of the X-ray.

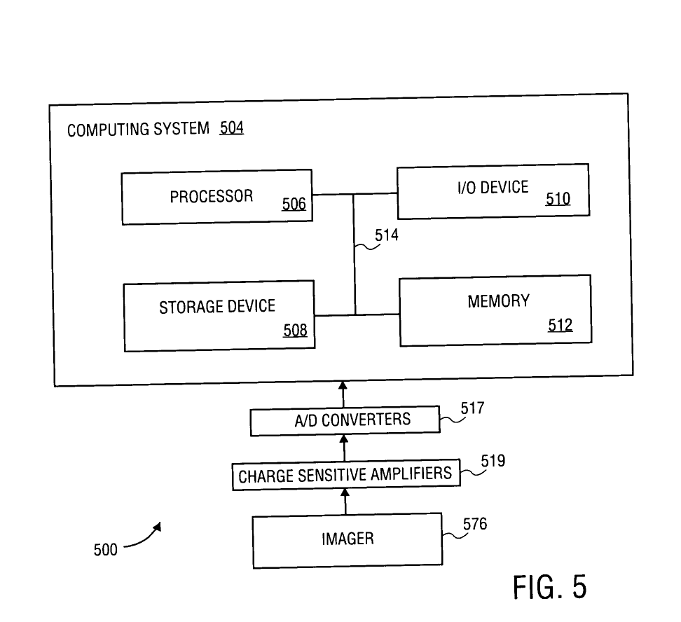

In one embodiment, an x-ray detector 576 may be constructed, for example, as a flat panel detector with a matrix of photodetectors 200 with readout electronics to transfer the light (e.g., x-ray) intensity of a pixel to a digital signal for processing. The readout electronics may be disposed around the edges of the detector to facilitate reception of incident x-rays on either surface of the detector. The flat panel detector may use, for example, TFT switch matrix coupled to the detectors 200 and capacitors to collect charge produced by the current from detectors 200. The charge is collected, amplified and processed as discussed below in relation to FIG. 5. The choice of bias voltage may determine the sensitivity of the detector 200. The bias voltage may be configured by system 500 of FIG. 5.

FIG. 5 illustrates one embodiment of an x-ray detection system. X-ray detection system 500 includes a computing device 504 coupled to a flat panel detector 576. As previously mentioned, flat panel detector 576 may operate by accumulating charge on capacitors generated by pixels of photodetectors 200. Typically, many pixels are arranged over a surface of flat panel detector 576 where, for example, TFTs at each pixel connect a charged capacitor (not shown) to charge sensitive amplifier 519 at the appropriate time. Charge sensitive amplifier 519 drives analog to digital (A/D) converter 517 that, in turn, converts the analog signals received from amplifier 519 into digital signals for processing by computer device 504. A/D converter 517 may be coupled to computing device 504 using, for example, I/O device 510 or interconnect 514. A/D converter 517 and charge sensitive amplifiers 519 may reside within computing device 504 or flat panel detector 576 or external to either device. Amplifiers 519 integrate the charges accumulated in the pixels of the flat panel detector 576 and provide signals proportional to the received x-ray dose. Amplifiers 519 transmit these signals to A/D converter 517. A/D converter 517 translates the charge signals to digital values that are provided to computing device 504 for further processing. Although the operation of switch matrix may be discussed herein in relation to a TFT matrix, such is only for ease of discussion. Alternatively, other types of switch devices, such as switching diodes (e.g., single and/or double diodes) may also be used.

In the foregoing detailed description, the method and apparatus of the present invention has been described with reference to specific exemplary embodiments thereof. It will, however, be evident that various modifications and changes may be made thereto without departing from the broader spirit and scope of the present invention. In particular, the separate blocks of the various block diagrams represent functional blocks of methods or apparatuses and are not necessarily indicative of physical or logical separations or of an order of operation inherent in the spirit and scope of the present invention. Moreover, the foregoing materials are provided by way of example as they represent the materials used in photoconductors. It will be appreciated that other semiconducting materials or other materials may be used. Any material that has improved corrosion resistance and otherwise satisfies the desired electrical parameters may be used. The present specification and figures are accordingly to be regarded as illustrative rather than restrictive.

1. A photodetector, comprising:
a plurality of semiconductor materials forming a heterojunction, the plurality of semiconductor materials comprising:
a first semiconductor material;
a second semiconductor material coupled to the first semiconductor material, the first and second semiconductor materials being halides.

2. The photodetector of claim 1, wherein the first and second semiconductor materials have approximately the same band gap.

3. The photodetector of claim 1, wherein the first semiconductor material comprises an iodide compound and the second semiconductor material comprises mercuric iodide.

4. The photodetector of claim 3, wherein the first semiconductor material comprises lead iodide.

5. The photodetector of claim 1, further comprising:
a first contact; and
a second contact, wherein the first plurality of semiconductor materials are disposed between the first and second contacts.

6. The photodetector of claim 5, wherein at least one of the first and second contacts comprises palladium.

7. The photodetector of claim 5, wherein the second semiconductor material comprises mercuric iodide and the first semiconductor material is less chemically reactive than mercuric iodide with the contacts.

8. The photodetector of claim 1, wherein the second semiconductor material is thicker than the first semiconductor material.

9. The photodetector of claim 8, wherein the first semiconductor material has a first thickness less than approximately 250 microns.

10. The photodetector of claim 9, wherein the first semiconductor material has a first thickness less than approximately 50 microns.

11. The photodetector of claim 4, wherein the second semiconductor material is thicker than the first semiconductor material.

12. The photodetector of claim 11, wherein the first semiconductor material has a first thickness less than approximately 250 microns.

13. The photodetector of claim 12, wherein the first semiconductor material has a first thickness less than approximately 50 microns.

14. The photodetector of claim 4, wherein the plurality of semiconductor materials further comprises a third semiconductor material comprising lead iodide coupled to the second semiconductor material.

15. The photodetector of claim 14, wherein the third semiconductor material has a third thickness less than approximately 50 microns.

16. The photodetector of claim 1, wherein the second semiconductor material has a conductivity type different than the first semiconductor material.

17. The photodetector of claim 16, wherein the band gaps of the first and second semiconductor materials are within 10 percent of each other.

18. The photodetector of claim 17, wherein the first semiconductor material comprises mercuric iodide and the second semiconductor material comprises lead iodide.

19. The photodetector of claim 18, wherein the second semiconductor material is thicker than the first semiconductor material.

20. The photodetector of claim 18, wherein the plurality of semiconductor materials further comprises a third semiconductor material comprising lead iodide coupled to the second semiconductor material.

21. The photodetector of claim 1, wherein at least one of the first and second semiconductor materials comprises an iodide compound and wherein the first semiconductor material comprises bismuth iodide.

22. The photodetector of claim 21, wherein the second semiconductor material comprises mercuric iodide.

23. The photodetector of claim 21, wherein the first semiconductor material comprises lead iodide.

24. The photodetector of claim 1, wherein one of the first and second semiconductor materials comprises an iodide compound and the other of the first and second semiconductor materials comprises thallium bromide.

25. The photodetector of claim 24, wherein the one of the first and second semiconductor materials that comprises an iodide compound further comprises mercuric iodide.

26. The photodetector of claim 24, wherein the one of the first and second semiconductor materials that comprises an iodide compound further comprises lead iodide.

27. The photodetector of claim 1, wherein the photodetector is coupled to a negative bias.

28. The photodetector of claim 5, wherein the first contact is coupled to ground and the second contact is coupled to a negative voltage.

29. The photodetector of claim 8, wherein the first contact is coupled to ground and the second contact is coupled to a negative voltage.

30. A photodetector, comprising:
a first semiconductor material;
a second semiconductor material coupled to the first semiconductor material forming a heterojunction structure;
a contact coupled to the second semiconductor material, wherein the first and second semiconductor materials comprise means for reducing a chemical reaction with the contact; and
means for reducing dark current in the heterojunction structure.

31. A photodetector, comprising:
a first semiconductor material; and
a second semiconductor material coupled to the first semiconductor material; and
a contact coupled to the second semiconductor material, wherein the second semiconductor material is less corrosive than the first semiconductor material to the contact.

32. The photodetector of claim 31, wherein the first and second semiconductor materials are halides.

33. The photodetector of claim 32, wherein the first and second semiconductor materials comprise iodide.

34. The photodetector of claim 33, wherein the first semiconductor material is lead iodide.

35. The photodetector of claim 34, wherein the second semiconductor material is mercuric iodide.

36. The photodetector of claim 33, wherein the second semiconductor material is mercuric iodide.

37. The photodetector of claim 33, wherein the first semiconductor material is bismuth iodide.

38-48. (Canceled)
